(19) United States
(12) Patent Application Publication
(10) Pub. No.: US 2026/0262228 A1
(43) Pub. Date: Sep. 3, 2026

(54) SEMICONDUCTOR DEVICE AND METHOD OF MANUFACTURING SEMICONDUCTOR DEVICE

(71) Applicant: SK hynix Inc., Icheon-si (KR)

(72) Inventor: Nam Kyun PARK, Icheon-si (KR)

(21) Appl. No.: 19/278,065

(22) Filed: Jul. 23, 2025

(30) Foreign Application Priority Data
Feb. 28, 2025 (KR) 10-2025-0026462

(51) Int. Cl. H10B 63/00

(52) U.S. Cl. CPC H10B 63/80

(57) ABSTRACT

A semiconductor device includes a first row line, a first column line positioned on the first row line, a first memory cell positioned between the first row and first column lines and included in a first current path, a third row line, a third column line positioned on the third row line, a third memory cell positioned between the third row and third column lines and included in a third current path longer than the first current path, first contact plugs including first and third ones electrically connected to the first and third row lines, respectively, second contact plugs including first and third ones electrically connected to the first and third column lines, respectively, a first barrier pattern positioned between the first one of the first contact plugs and the first row line, and a second barrier pattern positioned between the first barrier pattern and the first row line.

### CROSS-REFERENCE TO RELATED APPLICATION

This application claims priority under 35 U.S.C. §119 to Korean Patent Application No. 10-2025-0026462 filed on February 28, 2025, which is incorporated herein by reference in its entirety.

### BACKGROUND

### 1. Technical Field

The present disclosure relates to an electronic device and a method of manufacturing the electronic device, and more particularly, to a semiconductor device and a method of manufacturing the semiconductor device.

### 2. Related Art

An integration degree of a semiconductor device is mainly determined by an area occupied by a unit memory cell. Recently, as improvement in an integration degree of a semiconductor device in which a memory cell is formed as a single layer on a substrate reaches a limit, a three-dimensional semiconductor device in which memory cells are stacked on a substrate is being proposed. In addition, various structures and manufacturing methods are being developed in order to improve operation reliability of the semiconductor device.

### SAMMARY

According to an embodiment of the present disclosure, a semiconductor device may include a first row line, a first column line positioned on the first row line, a first memory cell positioned between the first row line and the first column line, a first current path including the first memory cell, a third row line, a third column line positioned on the third row line, a third memory cell positioned between the third row line and the third column line, a third current path that includes the third memory cell being longer than the first current path, first contact plugs including a first one and a third one, the first one and the third one of the first contact plugs electrically connected to the first row line and the third row line, respectively, second contact plugs including a first one and a third one, the first one and the third one of the second contact plugs electrically connected to the first column line and the third column line, respectively, a first barrier pattern positioned between the first one of the first contact plugs and the first row line, and a second barrier pattern positioned between the first barrier pattern and the first row line.

According to an embodiment of the present disclosure, a semiconductor device may include a first row line having a first grain size, a first column line positioned on the first row line, a first memory cell positioned between the first row line and the first column line, a first current path including the first memory cell, a second row line having a second grain size greater than the first grain size, a second column line positioned on the second row line, a second memory cell positioned between the second row line and the second column line, a second current path that includes the second memory cell being longer than the first current path, first contact plugs including a first one and a second one, the first one and the second one of the first contact plugs electrically connected to the first row line and the second row line, respectively, and second contact plugs including a first one and a second one, the first one and the second one of the second contact plugs electrically connected to the first column line and the second column line, respectively.

### BRIEF DESCRIPTION OF THE DRAWINGS

FIG. 1 is a drawing illustrating a semiconductor device according to an embodiment of the present disclosure.

FIGS. 2A and 2B are drawings illustrating a semiconductor device according to an embodiment of the present disclosure.

FIGS. 3A, 3B, 3C, 4A, 4B, and 4C, are drawings illustrating a semiconductor device according to an embodiment of the present disclosure.

FIGS. 5A and 5B are diagrams illustrating a semiconductor device according to an embodiment of the present disclosure.

FIGS. 6A, 6B, 6C, 6D, 7A, 7B, 7C, 7D, 8A, 8B, 8C, 8D, 9A, 9B, 9C, 9D, 10A, 10B, 10C, 10D, 10E, 10F, and 10G, are drawings illustrating a method of manufacturing a semiconductor device according to an embodiment of the present disclosure.

### DETAILED DESCRIPTION

Embodiments of the present disclosure provides a semiconductor device and a method of manufacturing the semiconductor device having a stable structure and an improved characteristic.

According to the present technology, a semiconductor device having a stable structure and improved reliability may be provided. As used herein, including in the claims, the term 'or' in a list of items (e.g., a list introduced by phrases such as 'at least one of,' 'one or more of,' or 'one or both of') is intended to be inclusive unless explicitly stated otherwise. Specifically, the term 'or' should be interpreted to cover any individual item in the list, any combination of items in the list, or all items in the list. For example, a phrase such as 'at least one of A, B, or C' is intended to encompass A alone, B alone, C alone, any combination of A and B, A and C, or B and C, as well as A, B, and C together. This inclusive interpretation applies unless an explicit indication to the contrary is provided in a particular context. Moreover, a first element “on” a second element indicates that the first element can be “directly on” the second element, or that at least one intervening element can be interposed between the first and second elements.

Hereinafter, some embodiments of the present disclosure are described with reference to the accompanying drawings.

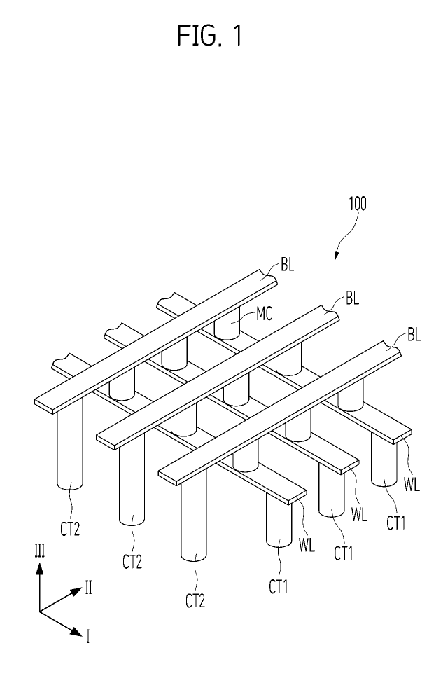

FIG. 1 is a drawing illustrating a semiconductor device according to an embodiment of the present disclosure.

Referring to FIG. 1, the semiconductor device may include row lines WL, column lines BL, memory cells MC, first contact plugs CT1, and second contact plugs CT2.

A memory cell array may include column lines BL and row lines WL positioned at different levels. For example, the column lines BL may be positioned on the row lines WL. In addition, the row lines WL may extend in a first direction I, and the column lines BL may extend in a second direction II crossing the first direction I.

The row lines WL may be connected to the first contact plugs CT1, respectively. The row lines WL may be connected to one or more peripheral circuits through the first contact plugs CT1. The column lines BL may be connected to the second contact plugs CT2, respectively. The column lines BL may be connected to one or more peripheral circuits through the second contact plugs CT2.

The memory cells MC may be positioned between the row lines WL and the column lines BL, respectively. In addition, the memory cells MC may be arranged in the first direction I and the second direction II. In addition, each of the memory cells MC may be a memory stack. Here, a third direction III may be a direction crossing the first direction I and the second direction II, and may be a direction perpendicular to the first direction I and the second direction II.

Although this drawing shows a specific case where the memory cell array has a single deck structure, embodiments of the present disclosure are not limited thereto, and the memory cells MC may also be stacked in the third direction III. For example, the memory cell array may have a multi deck structure in which the row lines WL and the column lines BL are alternately stacked in the third direction III. In this case, memory cells may be respectively positioned between the row lines WL and column lines BL alternately stacked.

According to the structure described above, by arranging the memory cells MC in a cross point array structure, an integration degree of a memory element may be improved. In addition, by stacking the memory cells MC in the multi deck structure, the integration degree of the memory element may be further improved.

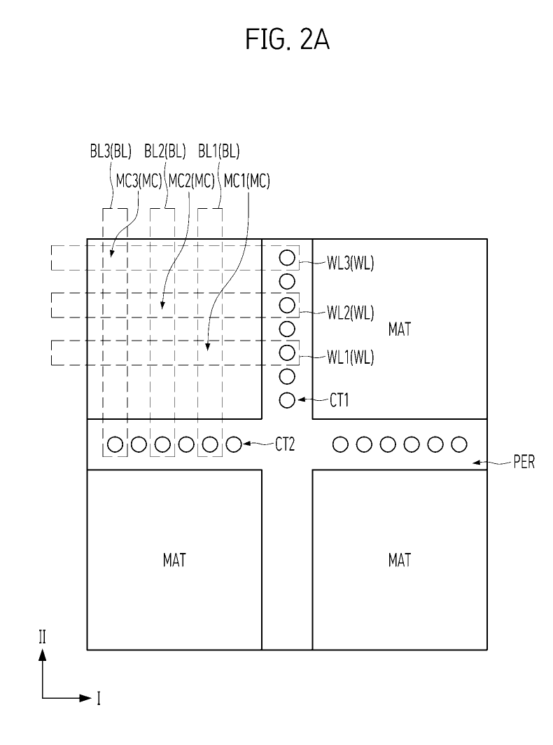

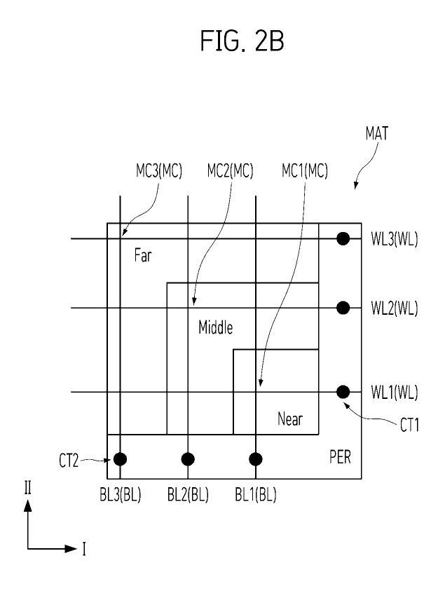

FIGS. 2A and 2B are drawings illustrating a semiconductor device according to an embodiment of the present disclosure. Hereinafter, content that overlap the content described above may omitted for the interest of brevity.

Referring to FIGS. 2A and 2B, the semiconductor device may include a plurality of mats MAT. For example, the mat MAT may be a driving unit in which a write, read, or erase operation is performed. For example, the write, read, or erase operation may be independently performed on each of the mats MAT.

The first and second contact plugs CT1 and CT2 may be positioned around a circumference of the mat MAT or between neighboring mats MAT. The first and second contact plugs CT1 and CT2 may be positioned in a peripheral circuit region PER. Here, the peripheral circuit region PER may be a region around the circumference of the mat MAT or between the neighboring mats MAT. The first contact plugs CT1 may be arranged in the second direction II, between mats MAT neighboring in the first direction I. The second contact plugs CT2 may be arranged in the first direction I, between mats MAT neighboring in the second direction II.

The mat MAT may include the memory cells MC arranged in the first direction I and the second direction II. In addition, the memory cells MC included in the MAT may be connected to the first contact plugs CT1 through the row lines WL, and may be connected to the second contact plugs CT2 through the column lines BL. Therefore, the memory cells MC each may have a current path through which a current flows during the write, read, or erase operation.

The current path may be a path through which a current flows from the first contact plug (or a first one of the first contact plugs) CT1 to the second contact plug (or a first one of the second contact plugs) CT2 through the memory cell MC. For example, a first current path from the first contact plug CT1 to the second contact plug CT2 may include a first memory cell MC1. Here, the first current path may be a sum of a path of a first row line WL1 from the first contact plug CT1 to the first memory cell MC1, a path through the first memory cell MC1, and a path of a first column line BL1 from the first memory cell MC1 to the second contact plug CT2.

A second memory cell MC2 may have a second current path from the first contact plug (or a second one of the first contact plugs) CT1 to the second contact plug (or a second one of the second contact plugs) CT2 through the second memory cell MC2. For example, a second current path from the first contact plug CT1 to the second contact plug CT2 may include a second memory cell MC2. Here, the second current path may be a sum of a path of a second row line WL2 from the first contact plug CT1 to the second memory cell MC2, a path through the second memory cell MC2, and a path of a second column line BL2 from the second memory cell MC2 to the second contact plug CT2.

A third memory cell MC3 may have a third current path from the first contact plug (or a third one of the first contact plugs) CT1 to the second contact plug (or a third one of the second contact plugs) CT2 through the third memory cell MC3. For example, a third current path from the first contact plug CT1 to the second contact plug CT2 may include a third memory cell MC3. Here, the third current path may be a sum of a path of a third row line WL3 from the first contact plug CT1 to the third memory cell MC3, a path through the third memory cell MC3, and a path of a third column line BL3 from the third memory cell MC3 to the second contact plug CT2.

According to a position in the MAT, the memory cells MC may have different current paths. For example, the second current path of the second memory cell MC2 may be longer than the first current path of the first memory cell MC1. The third current path of the third memory cell MC3 may be longer than the second current path of the second memory cell MC2. Therefore, a region of the MAT may be divided according to a length of the current path.

Each region in the MAT may be classified into a corresponding one of predetermined regions according to the length of the current path. A NEAR region may be a region where memory cells each having a relatively short current path are positioned. A FAR region may be a region where memory cells each having a relatively long current path are positioned. A MIDDLE region may be a region except for the NEAR region and the FAR region in the MAT. For example, the first memory cell MC1 in the first current path may be positioned in the NEAR region, the second memory cell MC2 in the second current path may be positioned in the MIDDLE region, and the third memory cell MC3 in the third current path may be positioned in the FAR region.

The memory cells MC1, MC2, and MC3 positioned in the NEAR region, the MIDDLE region, and the FAR region may have different current paths, and total resistance values of the current paths may vary according to the different current paths. For example, the first current path may have a first resistance, the second current path may have a second resistance, and the third current path may have a third resistance. Here, the first resistance may be less than the second resistance, and the second resistance may be less than the third resistance.

In this case, an amount of a current applied to the memory cells MC1, MC2, and MC3 during driving may be different. For example, in a case of the first memory cell MC1 positioned in the NEAR region, a relatively large current may be applied because the first resistance is relatively small. Therefore, overshoot may occur because a current may be excessively applied to the first memory cell MC1 of the NEAR region, and the first memory cell MC1 may be damaged.

In order to compensate for the resistance difference according to the current path, at least one or more barrier patterns may be added between the first contact plugs CT1 and the row lines WL and/or between the second contact plugs CT2 and the column lines BL. For example, at least one or more barrier patterns may be added between the first contact plug CT1 and the first row line WL1. At least one or more barrier patterns may be added between the second contact plug CT2 and the first column line BL1. Here, the barrier patterns may have resistivity greater than resistivity of the row lines WL.

In this case, the first current path from the first contact plug (or the first one of the first contact plugs) CT1 to the second contact plug (or the first one of the second contact plugs) CT2 includes at least one barrier pattern, the first row line WL1, the first memory cell MC1, at least one barrier pattern, and the first column line BL1. The first resistance of the first current path may be increased by one or more barrier patterns. Here, the increased first resistance may be substantially equal to the third resistance of the third current path. For example, a difference between the first resistance and the third resistance may not be greater than 5%, 3%, or 1% of an average value of the first resistance and the third resistance. Therefore, because the first resistance in the first current path is increased compared to that in a conventional semiconductor device, a relatively less current may be applied during driving. Accordingly, overshoot may be suppressed in the first memory cell MC1 to substantially prevent damage to the first memory cell MC1.

Similarly, one or more barrier patterns may be added between the first contact plug (or a second one of the first contact plugs) CT1 and the second row line WL2. One or more barrier patterns may be added between the second contact plug (or a second one of the second contact plugs) CT2 and the second column line BL2. In this case, the second resistance of the second current path may be increased by one or more barrier patterns. Here, the increased second resistance may be substantially equal to the third resistance. Therefore, a relatively small current compared to the absence of the one or more barrier patterns may be applied in the second current path as well.

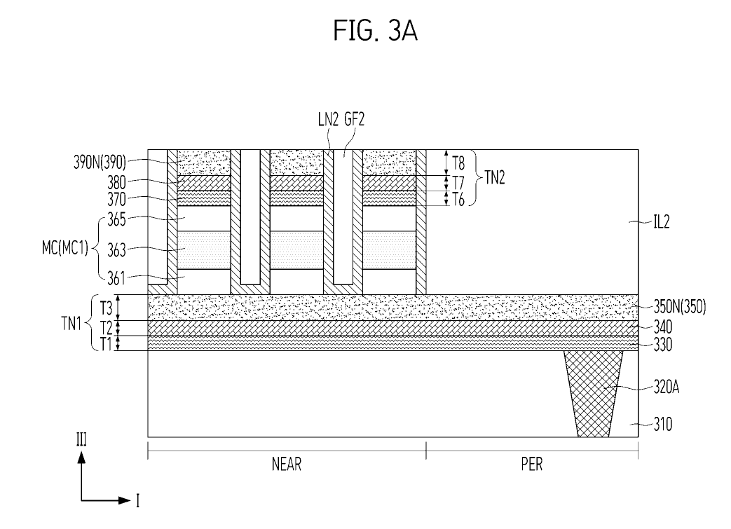

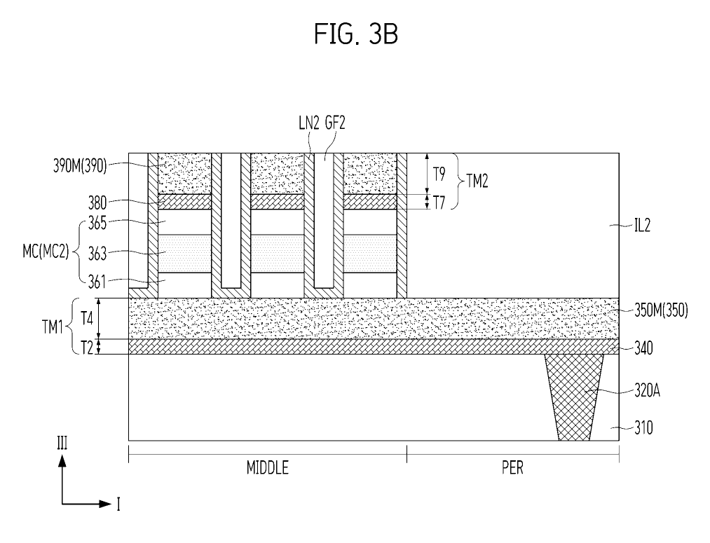

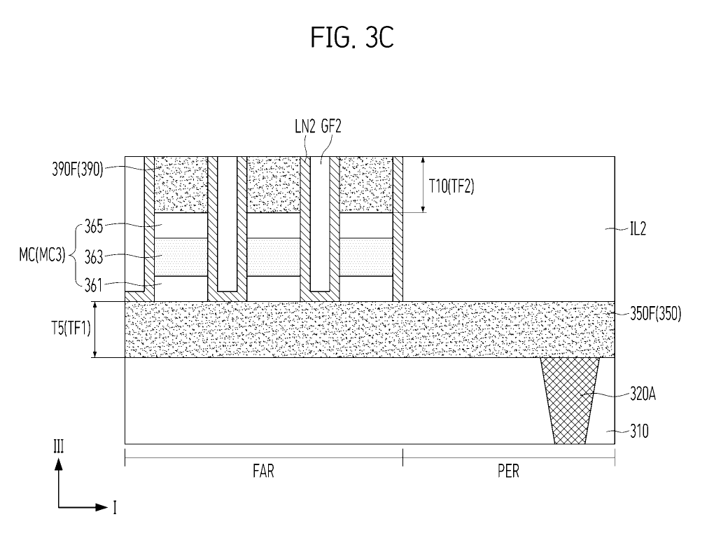

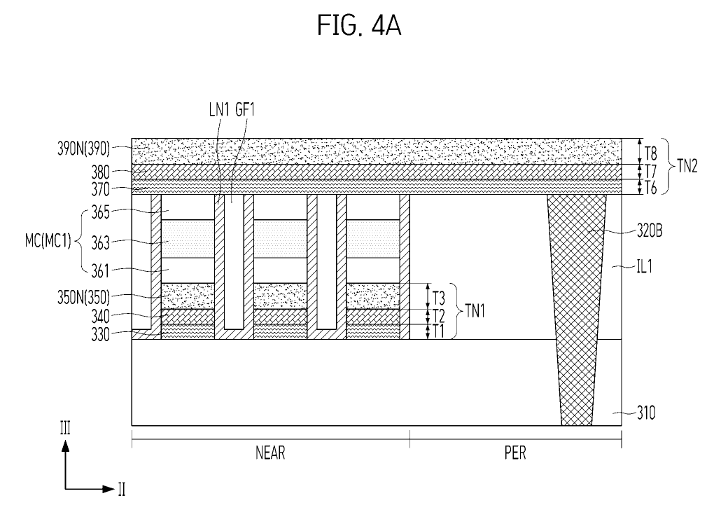

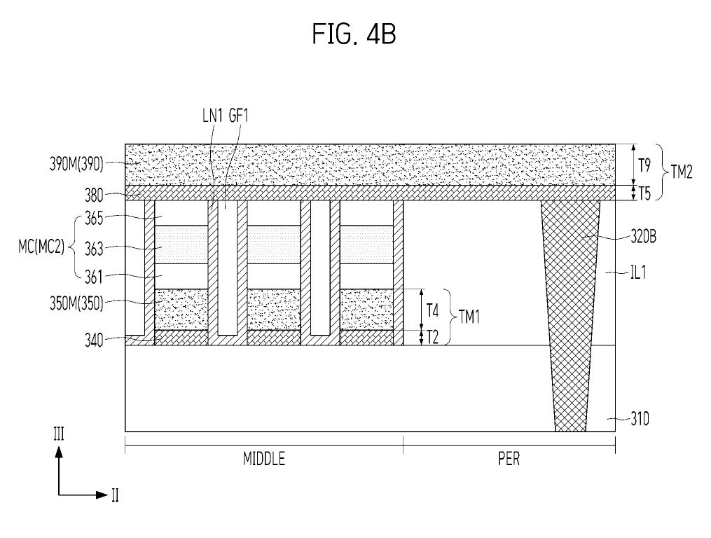

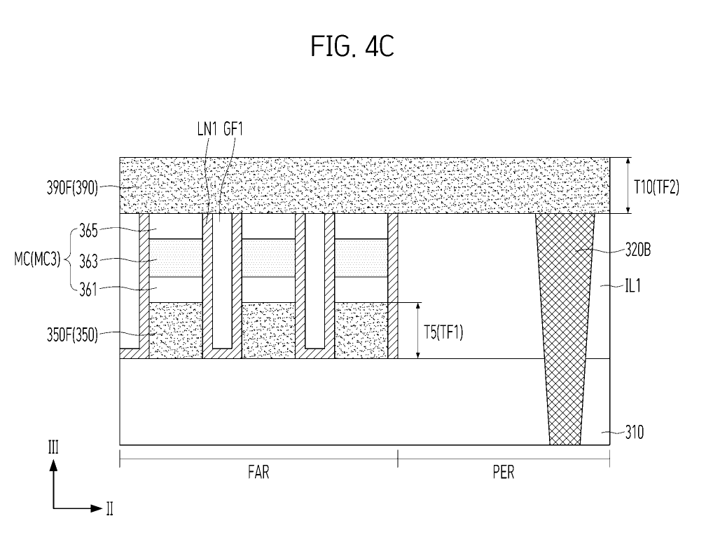

FIGS. 3A, 3B, 3C, 4A, 4B, and 4C, are drawings illustrating a semiconductor device according to an embodiment of the present disclosure. Hereinafter, contents that overlap the contents described above may be omitted for the interest of brevity.

Referring to FIGS. 3A to 3C and 4A to 4C, the semiconductor device may include row lines 350, column lines 390, memory cells MC, first barrier patterns 330, second barrier patterns 340, first contact plugs 320A, and second contact plugs 320B. The semiconductor device may further include an interlayer insulating layer 310, a first gap insulating layer IL1, a second gap insulating layer IL2, first liner patterns LN1, second liner patterns LN2, first gap fill patterns GF1, and second gap fill patterns GF2.

The first contact plugs 320A may be positioned in a peripheral circuit region PER. The first contact plugs 320A may be positioned in the interlayer insulating layer 310. The interlayer insulating layer 310 may be positioned on a substrate (not shown). A peripheral circuit may be positioned on the substrate, and the first contact plugs 320A may be connected to the peripheral circuit through an interconnection structure. The interlayer insulating layer 310 may include an insulating material such as an oxide. The first contact plugs 320A may include a conductive material such as tungsten.

The row lines 350 may be positioned on the first contact plugs 320A. The row lines 350 may be electrically connected to the first contact plugs 320A, respectively. The row lines 350 may extend in a first direction I. The row line 350 extending through a NEAR region may be a first row line 350N. The row line 350 extending through a MIDDLE region may be a second row line 350M. The row line 350 extending through a FAR region may be a third row line 350F.

The first row line 350N may have a first grain size, and may have a third thickness T3. The second row line 350M may have a second grain size, and may have a fourth thickness T4. The third row line 350F may have a third grain size, and may have a fifth thickness T5. The third thickness T3 may be less than the fourth thickness T4. The fourth thickness T4 may be less than the fifth thickness T5. Here, the row lines 350 may be used as a word line or a bit line. The row lines 350 may include a conductive material such as tungsten.

A grain size of a layer formed on a substrate may vary according to a material of the substrate (base). As the grain size is decreased, the density of grain boundaries may be increased, and thus resistivity may be increased because the grain boundaries interfere with movement of an electron. The first grain size may be less than the second grain size. The second grain size may be less than the third grain size. In other words, resistivity of the first row line 350N may be greater than resistivity of the second row line 350M. The resistivity of the second row line 350M may be greater than resistivity of the third row line 350F.

The column lines 390 may be positioned on the row lines 350. The column lines 390 may extend in a second direction II crossing the first direction I. The column line 390 extending through the NEAR region may be a first column line 390N. The column line 390 extending through the MIDDLE region may be a second column line 390M. The column line 390 extending through the FAR region may be a third column line 390F.

The first column line 390N may have a fourth grain size, and may have an eighth thickness T8. The second column line 390M may have a fifth grain size, and may have a ninth thickness T9. The third column line 390F may have a sixth grain size, and may have a tenth thickness T10. The fourth grain size may be less than the fifth grain size, and the fifth grain size may be less than the sixth grain size. The eighth thickness T8 may be less than the ninth thickness T9, and the ninth thickness T9 may be less than the tenth thickness T10. Here, the column lines 390 may be used as a word line or a bit line. The column lines 390 may include a conductive material such as tungsten.

The second contact plugs 320B may be electrically connected to the column lines 390, respectively. The second contact plugs 320B may be positioned in the peripheral circuit region PER. The second contact plugs 320B may be positioned in the first gap insulating layer IL1. The first gap insulating layer IL1 may be positioned on the interlayer insulating layer 310. The second contact plugs 320B may be connected to the peripheral circuit(s) through the first contact plugs 320A and the interconnection structure. The first gap insulating layer IL1 may include an insulating material such as an oxide. The second contact plugs 320B may include a conductive material such as tungsten.

The memory cells MC may be arranged in the first direction I and the second direction II. The memory cells MC may be positioned between the row lines 350 and the column lines 390, respectively. The memory cells MC may include a first memory cell MC1 in a first current path through the NEAR region, a second memory cell MC2 in a second current path through the MIDDLE region, and a third memory cell MC3 in a third current path through the FAR region. The first memory cell MC1 may be positioned between the first row line 350N and the first column line 390N, the second memory cell MC2 may be positioned between the second row line 350M and the second column line 390M, and the third memory cell MC3 may be positioned between the third row line 350F and the third column line 390F.

The memory cell MC may include a lower electrode pattern 361, a variable resistance pattern 363, and an upper electrode pattern 365. The lower electrode pattern 361 may be positioned on the row line 350. The lower electrode pattern 361 may be a portion of the row line 350, or may be electrically connected to the row line 350. The upper electrode pattern 365 may be positioned on the lower electrode pattern 361. The upper electrode pattern 365 may be a portion of the column line 390, or may be electrically connected to the column line 390. The variable resistance pattern 363 may be positioned between the lower electrode pattern 361 and the upper electrode pattern 365.

The lower electrode pattern 361 and/or the upper electrode pattern 365 may include polysilicon, tungsten (W), tungsten nitride (WNx), tungsten silicide (WSix), titanium (Ti), titanium nitride (TiNx), titanium silicon nitride (TiSiN), titanium aluminum nitride (TiAlN), tantalum (Ta), tantalum nitride (TaN), tantalum silicon nitride (TaSiN), tantalum aluminum nitride (TaAlN), carbon (C), silicon carbide (SiC), silicon carbon nitride (SiCN), copper (Cu), zinc (Zn), nickel (Ni), cobalt (Co), lead (Pb), platinum (Pt), molybdenum (Mo), ruthenium (Ru), or the like, and may include a combination thereof.

The variable resistance pattern 363 may be positioned between the lower electrode pattern 361 and the upper electrode pattern 365. The variable resistance pattern 363 may maintain an amorphous state during a program operation, and may not change to a crystalline state after the program operation. In other words, a phase of the variable resistance pattern 363 may not change after the program operation. The variable resistance pattern 363 may be used as a data storage and as a selection element simultaneously. The variable resistance pattern 363 may include a resistive material, and may have a characteristic of reversibly changing between different resistance states according to an applied voltage or current. For example, the variable resistance pattern 363 may include a variable resistance material of which a resistance changes without a phase change, and may include a chalcogenide element. The variable resistance pattern 363 may include germanium (Ge), antimony (Sb), arsenic (As), silicon (Si), indium (In), tin (Sn), gallium (Ga), or the like, or may include a combination thereof.

The variable resistance pattern 363 may include a phase change material, and may include a chalcogenide. The variable resistance pattern 363 may include chalcogenide glass, a chalcogenide alloy, or the like. The variable resistance pattern 363 may change a phase according to the program operation. For example, the variable resistance pattern 363 may have a low-resistive crystalline state by a set operation. In addition, the variable resistance pattern 363 may have a high-resistive amorphous state by a reset operation. Therefore, data may be stored in the memory cell MC, by using a resistance difference according to the phase of the variable resistance pattern 363.

The variable resistance pattern 363 may include a metal oxide (e.g., a transition metal oxide), or may include a metal oxide such as a perovskite material. Therefore, data may be stored in the memory cell as an electrical path is generated or disappeared in the variable resistance pattern 363.

The variable resistance pattern 363 may have an MTJ structure, and may include a magnetization fix layer, a magnetization free layer, and a tunnel barrier layer interposed therebetween. For example, the magnetization fix layer and the magnetization free layer each may include a magnetic material, and the tunnel barrier layer may include an oxide such as magnesium (Mg), aluminum (Al), zinc (Zn), or titanium (Ti). Here, a magnetization direction of the magnetization free layer may be changed by spin torque of electrons in an applied current. Therefore, data may be stored in the memory cell MC according to a magnetization direction change of the magnetization free layer with respect to the magnetization direction of the magnetization fix layer.

In addition, the variable resistance pattern 363 may have a metal-insulator-metal (MIM) structure including a metal oxide. In this case, data may be stored in the memory cell MC by using a resistance change of the metal oxide that occurs by applying a relatively short electric pulse.

For reference, although not shown in this drawing, the semiconductor device may further include an intermediate electrode pattern and a switching pattern. For example, the semiconductor device may include a structure in which the lower electrode pattern 361, the switching pattern, the intermediate electrode pattern, the variable resistance pattern 363, and the upper electrode pattern 365 are sequentially stacked. In this case, the lower electrode pattern 361, the switching pattern, and the intermediate electrode pattern may configure a selection element. The selection element may be a diode, a PNP diode, a transistor, a vertical transistor, a bipolar junction transistor (BJT), a metal insulator transition (MIT) element, a mixed ionic-electronic conduction (MIEC) element, an ovonic threshold switching (OTS) element, or the like. For example, the switching pattern 123 may include a chalcogenide material. In addition, the intermediate electrode pattern, the variable resistance pattern 363, and the upper electrode pattern 365 may configure a memory element. The memory element and the selection element may share the intermediate electrode pattern.

The first barrier pattern 330 may be positioned between the first contact plug 320A and the row line 350. For example, the first barrier pattern 330 may be positioned between the first contact plug (or a first one of the first contact plugs) 320A and the first row line 350N. The first barrier pattern 330 may have a first thickness T1. Resistivity of the first barrier pattern 330 may be greater than resistivity of the row lines 350. The first barrier pattern 330 may include a nitride. As an example, the first barrier pattern 330 may include tungsten silicon nitride (WSiN). As another example, the first barrier pattern 330 may include titanium nitride (TiN).

The second barrier patterns 340 may be positioned between the first contact plugs 320A and the row lines 350. As an example, the second barrier pattern 340 may be positioned between the first barrier pattern 330 and the first row line 350N. As another example, the second barrier pattern 340 may be positioned between the first contact plug (or a second one of the first contact plugs) 320A and the second row line 350M. The second barrier patterns 340 may have a second thickness T2. Resistivity of the second barrier patterns 340 may be greater than resistivity of the row lines 350. The second barrier patterns 340 may include a nitride. As an example, the second barrier patterns 340 may include tungsten silicon nitride (WSiN). As another example, the second barrier patterns 340 may include titanium nitride (TiN).

A third barrier pattern 370 may be positioned between the second contact plug (or a first one of the second contact plugs) 320B and the first column line 390N. The third barrier pattern 370 may have a thickness similar to the thickness of the first barrier pattern and may include a material similar to the material of the first barrier pattern 330. The third barrier pattern 370 may have a sixth thickness T6. The third barrier pattern 370 may include tungsten silicon nitride (WSiN) or titanium nitride (TiN).

A fourth barrier pattern 380 may be positioned between the third barrier pattern 370 and the first column line 390N. The fourth barrier pattern 380 may be positioned between the second contact plug (or a second one of the second contact plugs) 320B and the second column line 390M. The fourth barrier pattern 380 may have a thickness similar to the thickness of the second barrier pattern 340 and may include a material similar to the material of the second barrier pattern 340. The fourth barrier pattern 380 may have a seventh thickness T7. The fourth barrier pattern 380 may include tungsten silicon nitride (WSiN) or titanium nitride (TiN).

A sum TN1 of the first thickness T1 of the first barrier pattern 330, the second thickness T2 of the second barrier pattern 340, and the third thickness T3 of the first row line 350N in the NEAR region may be substantially equal to the fifth thickness T5(TF1) of the third row line 350F in the FAR region. In addition, the sum TN1 of the first thickness T1 of the first barrier pattern 330, the second thickness T2 of the second barrier pattern 340, and the third thickness T3 of the first row line 350N in the NEAR region may be substantially equal to a sum TM1 of the second thickness T2 of the second barrier pattern 340 and the fourth thickness T4 of the second row line 350M in the MIDDLE region. For example, a difference between the sum TN1 of the thicknesses T1, T2, and T3 in the NEAR region and the thickness T5 in the FAR region may be not greater than 5%, 3%, or 1% of an average value of the sum TN1 and the thickness T5, and a difference between the sum TN1 of the thicknesses T1, T2, and T3 in the NEAR region and the sum TM1 of the thicknesses T2 and T4 may be not greater than 5%, 3%, or 1% of an average value of the sum TN1 and the sum TM1. In other words, the sum TN1 of the thicknesses of the first and second barrier patterns 330 and 340 and the first row line 350N in the NEAR region, the sum TM1 of the thicknesses of the second barrier pattern 340 and the second row line 350M in the MIDDLE region, and the thickness TF1 of the third row line 350F in the FAR region may be substantially equal.

A sum TN2 of the sixth thickness T6 of the third barrier pattern 370, the seventh thickness T7 of the fourth barrier pattern 380, and the eighth thickness T8 of the first column line 390N in the NEAR region may be substantially equal to the tenth thickness T10(TF2) of the third column line 390F in the FAR region. In addition, the sum TN2 of the sixth thickness T6 of the third barrier pattern 370, the seventh thickness T7 of the fourth barrier pattern 380, and the eighth thickness T8 of the first column line 390N in the NEAR region may be substantially equal to a sum TM2 of the seventh thickness T7 of the fourth barrier pattern 380 and the thickness T9 of the second column line 390M in the MIDDLE region. In other words, the sum TN2 of the thicknesses of the third and fourth barrier patterns 370 and 380 and the first column line 390N in the NEAR region, the sum TM2 of the thicknesses of the fourth barrier pattern 380 and the second column line 390M in the MIDDLE region, and the thickness TF2 of the third column line 390F in the FAR region may be substantially equal.

The first memory cell MC1 may have a first current path having a first resistance. For example, the first current path from the first contact plug (or the first one of the first contact plugs) 320A to the second contact plug (or the first one of the second contact plugs) 320B may include the first barrier pattern 330, the second barrier pattern 340, the first row line 350N, the first memory cell MC1, and the first column line 390N. Here, the first current path may further include a path from the first memory cell MC1 to the first column line 390N through the third barrier pattern 370 and the fourth barrier pattern 380. Here, the first current path may have the first resistance.

The second memory cell MC2 may have a second current path having a second resistance. For example, the second current path from the first contact plug (or the second one of the first contact plugs) 320A to the second contact plug (or the second one of the second contact plugs) 320B may include the second barrier pattern 340, the second row line 350M, the second memory cell MC2, and the second column line 390M. Here, the second current path may further include a path from the second memory cell MC2 to the second column line 390M through the fourth barrier pattern 380. Here, the second current path may have the second resistance.

The third memory cell MC3 may have a third current path having a third resistance. For example, the third current path from the first contact plug (or the third one of the first contact plugs) 320A to the second contact plug (or the third one of the second contact plugs) 320B may include the third row line 350F, the third memory cell MC3, and the third column line 390F.

Here, resistivity of the first and second barrier patterns 330 and 340 may be greater than resistivity of the row lines 350. In addition, resistivity of the third and fourth barrier patterns 370 and 380 may be greater than resistivity of the column lines 390. Resistivity of the first and second row lines 350N and 350M may be greater than resistivity the third row line 350F. In addition, resistivity of the first and second column lines 390N and 390M may be greater than resistivity of the third column line 390F. Moreover, in some embodiments, contact resistance between the first one of the first contact plugs 320A and the first barrier pattern 330 in FIG. 3A may be greater than contact resistance between the second one of the first contact plugs 320A and the second barrier pattern 340 in FIG. 3B, and/or the contact resistance between the second one of the first contact plugs 320A and the second barrier pattern 340 in FIG. 3B may be greater than contact resistance between the third one of the first contact plugs 320A and the third row line 350F in FIG. 3C.

As a result, the first resistance of the first current path, the second resistance of the second current path, and the third resistance of the third current path may be substantially equal. For example, a difference between the first resistance and the second resistance may not be greater than 5%, 3%, or 1% of an average value of the first resistance and the second resistance, and a difference between the first resistance and the third resistance may not be greater than 5%, 3%, or 1% of an average value of the first resistance and the third resistance. In other words, the first resistance of the first current path may be compensated by the first, second, third, and fourth barrier patterns 330, 340, 370, and 380, the first row line 350N, and the first column line 390N so that the first resistance of the first current path having a relatively short current path is substantially equal to the third resistance of the third current path. In addition, the second resistance of the second current path may be compensated by the second and fourth barrier patterns 340 and 380, the second row line 350M, and the second column line 390M so that the second resistance of the second current path is substantially equal to the third resistance.

When the memory cells MC are driven, a less current may flow through the first and second memory cells MC1 and MC2 compared to a case where the first, second, third, and fourth barrier patterns 330, 340, 370, and 380 do not exist, and a less current may flow through the first and second memory cells MC1 and MC2 compared to a case where a grain size of each of the first and second row lines 350N and 350M and the first and second column lines 390N and 390M is not smaller than that of the third row line 350F and the third column line 390F. Therefore, overshoot may not occur in the first and second memory cells MC1 and MC2 to substantially prevent damage to the first and second memory cells MC1 and MC2.

For reference, in this drawing, the first, second, third, and fourth barrier patterns 330, 340, 370, and 380 extend from the peripheral circuit region PER to the NEAR region and the MIDDLE region, but embodiments of the present disclosure are not limited thereto. For example, the first, second, third and fourth barrier patterns 330, 340, 370, and 380 may be positioned only in the peripheral circuit region PER.

In addition, although this drawing shows a case where all of the first and second barrier patterns 330 and 340 and the third and fourth barrier patterns 370 and 380 exist in the NEAR region, embodiments of the present disclosure are not limited thereto. For example, when the first and second barrier patterns 330 and 340 exist in the NEAR region, the third and fourth barrier patterns 370 and 380 may be omitted. As another example, when the third and fourth barrier patterns 370 and 380 exist, the first and second barrier patterns 330 and 340 may be omitted. In other words, when a total resistance of each of the first, second, and third current paths becomes substantially equal through the first and second barrier patterns 330 and 340, the third and fourth barrier patterns 370 and 380 may be omitted. Similarly, when the second barrier patterns 340 exist in the MIDDLE region, the fourth barrier patterns 380 may be omitted, and vice versa.

The first liner patterns LN1 may cover sidewalls of the memory cells MC neighboring in the second direction II along a profile of the memory cells MC. The second liner patterns LN2 may cover sidewalls of the memory cells MC neighboring in the first direction I along the profile of the memory cells MC. The first liner patterns LN1 and the second liner patterns LN2 may protect the memory cells MC in a process of manufacturing the semiconductor device. At least one of the first liner patterns LN1 or the second liner patterns LN2 may include a nitride.

The first gap fill patterns GF1 may be positioned between the memory cells MC neighboring in the second direction II. The second gap fill patterns GF2 may be positioned between the memory cells MC neighboring in the first direction I. The first and second liner patterns LN1 and LN2 may be positioned between the first and second gap fill patterns GF1 and GF2 and the memory cells MC. The first and second gap fill patterns GF1 and GF2 may include an insulating material such as an oxide.

According to the structure described above, a grain size of each of the first and second row lines 350N and 350M may be smaller than a grain size of the third row line 350F, and a grain size of each of the first and second column lines 390N and 390M may be smaller than a grain size of the third column line 390F.

In addition, the first and second barrier patterns 330 and 340 may be positioned between the first contact plug 320A and the first and second row lines 350N and 350M, and the third and fourth barrier patterns 370 and 380 may be positioned between the second contact plug 320B and the first and second column lines 390N and 390M.

In this case, the first resistance of the first current path including the first memory cell MC1, the second resistance of the second current path including the second memory cell MC2, and the third resistance including the third current path of the third memory cell MC3 may be substantially equal.

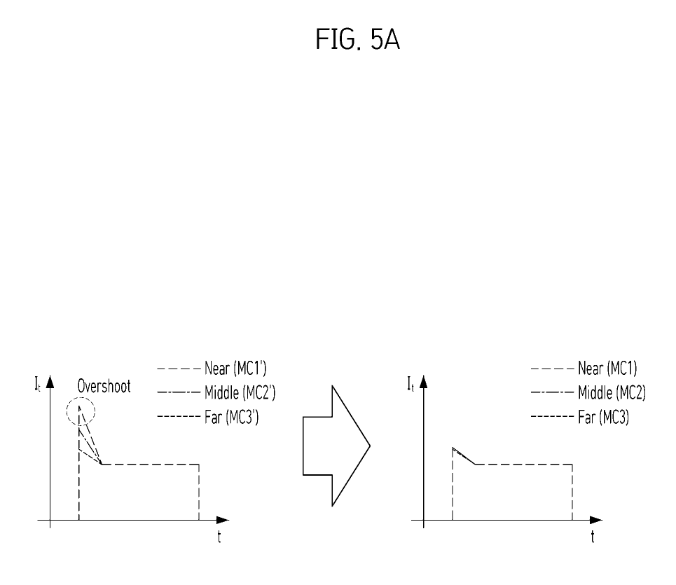

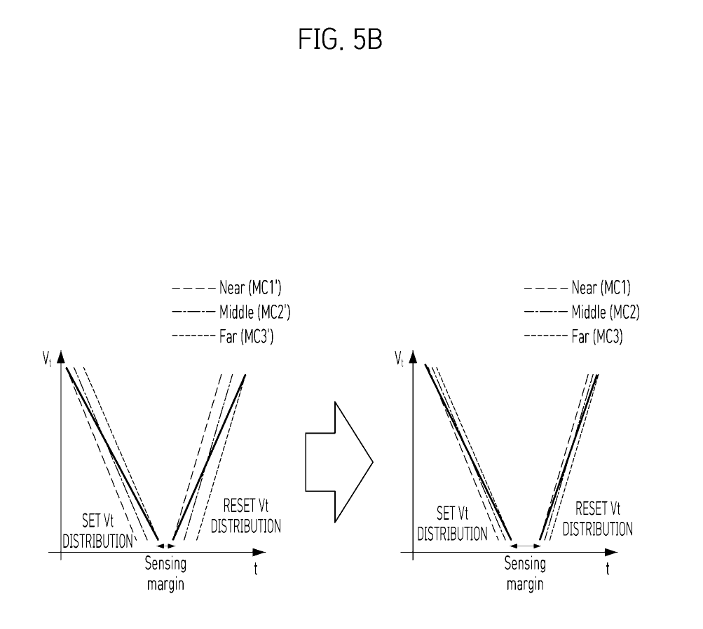

FIGS. 5A and 5B are diagrams illustrating a semiconductor device according to an embodiment of the present disclosure. Hereinafter, contents that overlap the contents described above may be omitted for the interest of brevity.

Referring to FIG. 5A, currents flowing during driving of first memory cells MC1’ and MC1 of a NEAR region, second memory cells MC2’ and MC2 of a MIDDLE region, and third memory cells MC3’ and MC3 of a FAR region may be compared.

When barrier patterns are not included in a first current path including the first memory cell MC1’ of the NEAR region, the first memory cell MC1’ may have a relatively short first current path, and the first current path may have a relatively small first resistance. In this case, when driving the first memory cell MC1’, a current may be excessively applied to the first memory cell MC1’, and thus overshoot may occur. Therefore, the first memory cell MC1’ may be damaged, and reliability may be deteriorated.

On the other hand, according to an embodiment of the present disclosure, when barrier patterns are included in a first current path including the first memory cell MC1 of the NEAR region, even though the first memory cell MC1 has a relatively short first current path, the first current path may have a first resistance compensated by the barrier patterns. In addition, by making a grain size of each of a first row line and a first column line included in the first current path of the first memory cell MC1 relatively small, the first current path may have a compensated first resistance. In other words, the first current path may have the first resistance substantially equal to a third resistance of a third current path of the third memory cell MC3. In this case, overshoot may not occur in the first memory cell MC1. Therefore, the first memory cell MC1 may not be damaged, and reliability may be improved.

Similarly, when barrier patterns are not included in a second current path of the second memory cell MC2’ of the MIDDLE region, or a grain size of each of a second row line and a second column line included in the second current path is not sufficiently small, overshoot may occur in the second memory cell MC2’ while driving the second memory cell MC2’. In contrast, according to an embodiment of the present disclosure, a barrier pattern may be included in a second current path including the second memory cell MC2 of the MIDDLE region, and/or a grain size of a second row line and a second column line may be sufficiently small to substantially prevent an occurrence of overshoot in the second memory cell MC2.

Referring to FIG. 5B, sensing margins of the first memory cells MC1’ and MC1 of the NEAR region, the second memory cells MC2’ and MC2 of the MIDDLE region, and the third memory cells MC3’ and MC3 of the FAR region may be compared.

In order to improve an operation characteristic of memory cells, a sensing margin is required to be secured. For example, when data is out of a range of the set sensing margin, an error may occur in the memory cells during a read, write, or erase operation.

The sensing margins may be compared through a distribution difference of a threshold voltage Vₜ during a SET or RESET operation in the NEAR region, the MIDDLE region, and the FAR region. When the first and second resistances of the first and second current paths are not compensated, because a resistance difference between the first, second and third current paths of the first, second and third memory cells MC1’, MC2’, and MC3’ of the NEAR region, the MIDDLE region and the FAR region exists, a difference of threshold voltages between the first, second and third memory cells MC1’, MC2’, and MC3’ may occur during the set operation or the reset operation. In other words, a distribution difference of a threshold voltage may occur between the first, second and third memory cells MC1’, MC2’, and MC3’ during the set operation or the reset operation. In this case, a sensing margin for sensing memory cells from the first memory cell MC1 of the NEAR region to the third memory cell MC3 of the FAR region during the set operation or the reset operation may be insufficient to ensure a reliable operation.

On the other hand, according to an embodiment of the present disclosure, the first and second resistances of the first and second current paths may be compensated, and in this case, because a resistance difference between the first, second and third current paths may be insignificant, a difference of a threshold voltage between the first, second and third memory cells MC1, MC2, and MC3 may be reduced. In other words, a distribution difference of a threshold voltage between the first, second, and third memory cells MC1, MC2, and MC3 may be reduced during the set operation or the reset operation. In this case, a sensing margin for sensing all memory cells from the first memory cell MC1 of the NEAR region to the third memory cell MC3 of the FAR region during the set operation or the reset operation may be secured.

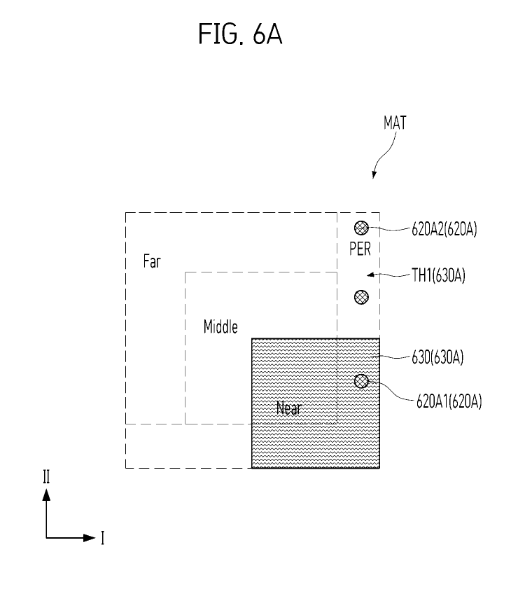

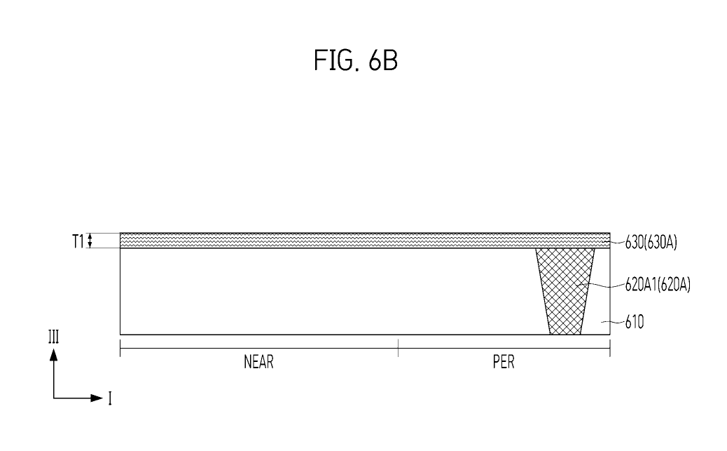

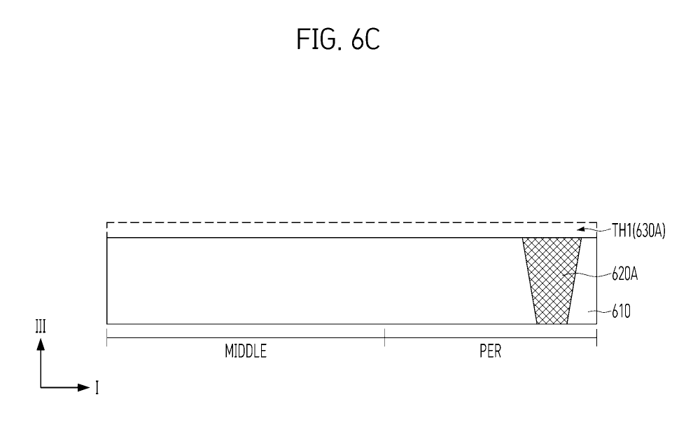

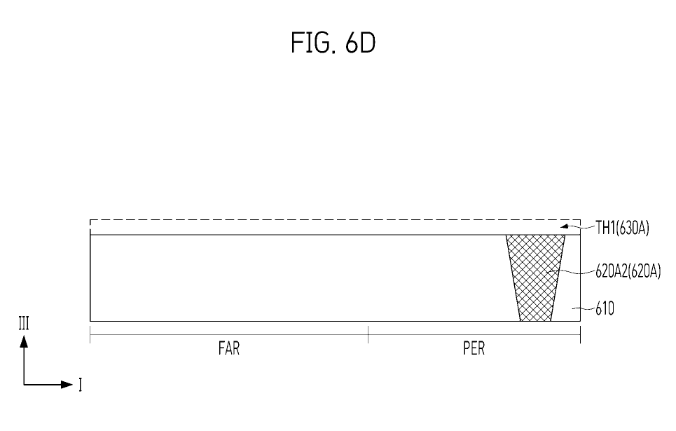

FIGS. 6A, 6B, 6C, 6D, 7A, 7B, 7C, 7D, 8A, 8B, 8C, 8D, 9A, 9B, 9C, 9D, 10A, 10B, 10C, 10D, 10E, 10F, and 10G, are drawings illustrating a method of manufacturing a semiconductor device according to an embodiment of the present disclosure. FIGS. 6A, 7A, 8A, 9A, and 10A, are plan views, FIGS. 6B, 7B, 8B, 9B, 10B, and 10E. are cross-sectional views for a NEAR region and a PER region, FIGS. 6C, 7C, 8C, 9C, 10C, and 10F, are cross-sectional views for a MIDDLE region and the PER region, and FIGS. 6D, 7D, 8D, 9D, 10D, and 10G, are cross-sectional views for a FAR region and the PER region. Hereinafter, contents that overlap the content described above may be omitted for the interest of brevity.

Referring to FIGS. 6A to 6D, first contact plugs 620A may be formed in the peripheral circuit region PER. The first contact plugs 620A may be formed in an interlayer insulating layer 610. Here, in order to distinguish the first contact plug 620A formed adjacent to the NEAR region and the first contact plug 620A formed adjacent to the FAR region, the first contact plug 620A formed adjacent to the NEAR region may be defined as a first contact plug 620A1, and the first contact plug 620A formed adjacent to the FAR region may be defined as a second contact plug 620A2. The interlayer insulating layer 610 may include an insulating material such as an oxide, and the first contact plugs 620A may include a conductive material such as tungsten.

Subsequently, a first barrier layer 630A may be formed in the NEAR region, the MIDDLE region, the FAR region, and the peripheral circuit region PER. A first barrier layer 630A may be formed on the interlayer insulating layer 610. The first barrier layer 630A may be formed on the first contact plugs 620A. For example, the first barrier layer 630A may be formed on the first contact plug 620A1 and the second contact plug 620A2. Here, the first barrier layer 630A may include at least one of tungsten silicon nitride (WSiN) or titanium nitride (TiN).

Subsequently, a first trench TH1 may be formed by removing a portion of the first barrier layer 630A formed in the MIDDLE region, the FAR region, and the peripheral circuit region PER. For example, the first trench TH1 may be formed by removing the first barrier layer 630A formed on the second contact plug 620A2. In addition, the first trench TH1 may be formed by removing the first barrier layer 630A formed in the MIDDLE region and the FAR region. In this case, a portion of the first barrier layer 630A formed on the first contact plug 620A1 may remain, and the remaining portion of the first barrier layer 630A may extend to the NEAR region. The remaining portion of the first barrier layer 630A may be referred to as a first barrier pattern 630.

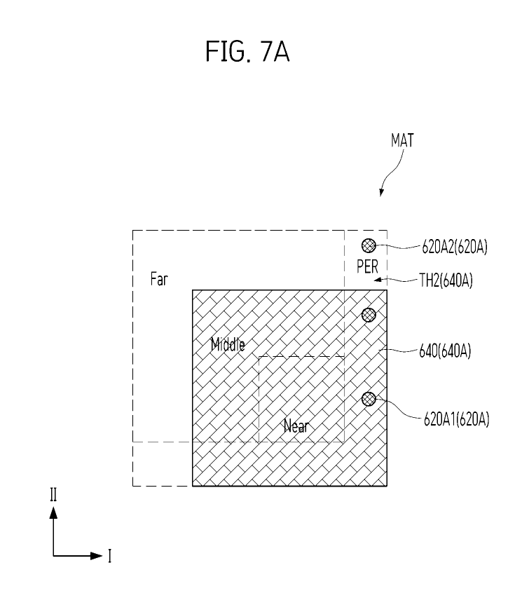

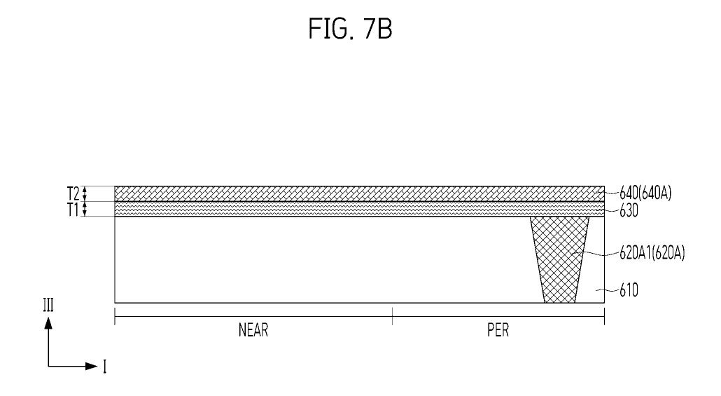

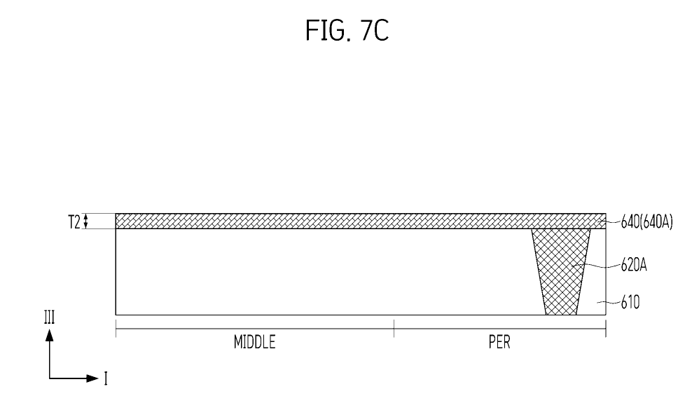

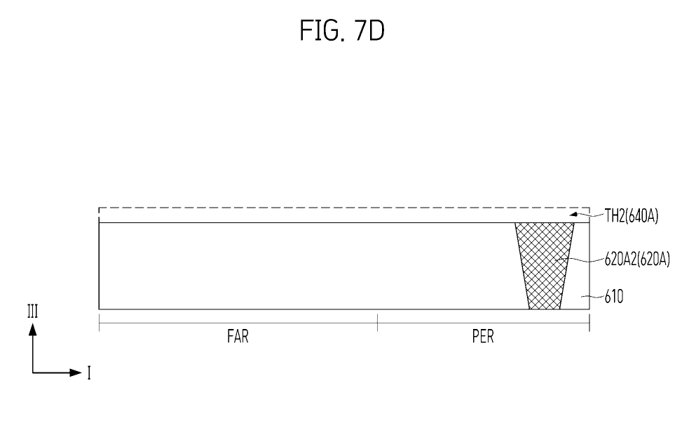

Referring to FIGS. 7A to 7D, a second barrier layer 640A may be formed in the NEAR region, the MIDDLE region, the FAR region, and the peripheral circuit region PER. The second barrier layer 640A may be formed on the first barrier pattern 630. In addition, the second barrier layer 640A may be formed on the second contact plug 620A2. Here, the second barrier layer 640A may include at least one of tungsten silicon nitride (WSiN) or titanium nitride (TiN).

Subsequently, a second trench TH2 may be formed by removing a portion of the second barrier layer 640A formed in the FAR region and the peripheral circuit region PER. For example, the second trench TH2 may be formed by removing the second barrier layer 640A formed on the second contact plug 620A2. In addition, the second trench TH2 may be formed by removing the second barrier layer 640A formed in the FAR region. In this case, a portion of the second barrier layer 640A may remain on the first barrier pattern 630, and the remaining portion of the second barrier layer 640A may extend to the MIDDLE region. The remaining portion of the second barrier layer 640A may be referred to as a second barrier pattern 640.

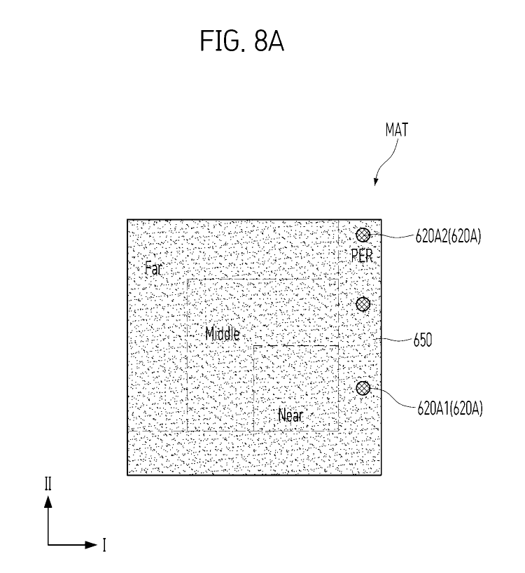

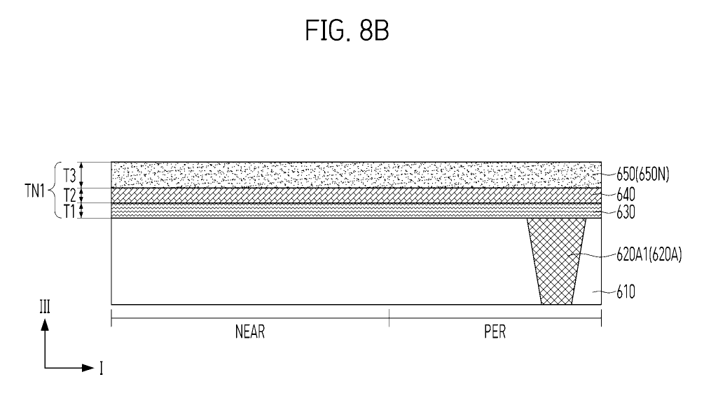

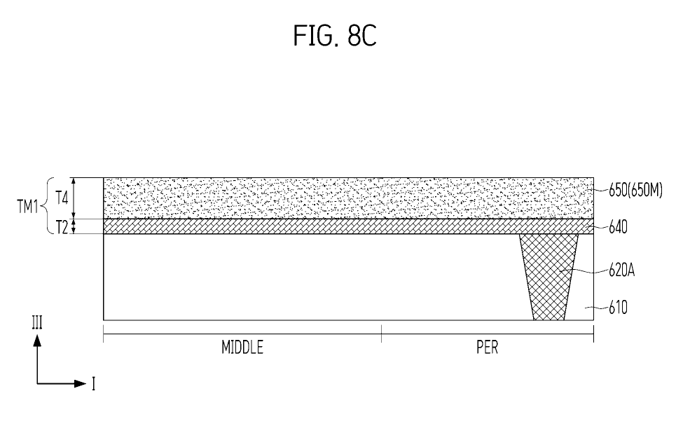

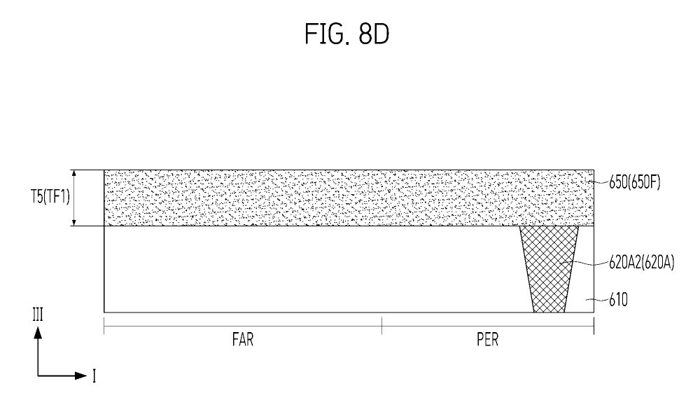

Referring to FIGS. 8A to 8D, a first conductive layer 650 may be formed in the NEAR region, the MIDDLE region, the FAR region, and the peripheral circuit region PER. For example, the first conductive layer 650 may be formed on the second barrier pattern 640 and the second contact plug 620A2. Here, the first conductive layer 650 may be formed to fill the NEAR region, the MIDDLE region, the FAR region, and the peripheral circuit region PER. The first conductive layer 650 may include a conductive material such as tungsten.

Because the first and second barrier patterns 630 and 640 are formed in the NEAR region and the MIDDLE region, a step may occur with the FAR region. In this case, the first conductive layer 650 may be planarized to remove the step between the regions. For example, the first conductive layer 650 may be planarized so that a sum TN1 of a thickness T1 of the first barrier pattern 630, a thickness T2 of the second barrier pattern 640, and a thickness of the first conductive layer 650N is substantially equal to a sum of a thickness T5 or TF1 of the first conductive layer 650F. In addition, the first conductive layer 650 may be planarized so that a sum TN1 of the thickness T1 of the first barrier pattern 630, the thickness T2 of the second barrier pattern 640, and the thickness of the first conductive layer 650N is substantially equal to a sum TM1 of the thickness T2 of the second barrier pattern 640 and the thickness of the first conductive layer 650M. In other words, the first conductive layer 650 may be planarized so that the thickness TN1 of material layers formed on the first contact plug 620A1 and in the NEAR region, the thickness TM1 of material layers formed on the first contact plug 620A and in the MIDDLE region, and the thickness TF1 of material layers formed on the second contact plug 620A2 and in the FAR region are substantially equal.

The first and second barrier patterns 630 and 640 each may include a material of which resistivity is greater than resistivity of the first conductive layer 650. For example, the first and second barrier patterns 630 and 640 may include a nitride, and the first conductive layer 650 may include tungsten. The first and second barrier patterns 630 and 640 may include a substantially equal material, or may include different materials. As an example, the first and second barrier patterns 630 and 640 may include a substantially equal material, and may include at least one of tungsten silicon nitride (WSiN) or titanium nitride (TiN). As another example, the first barrier pattern 630 may include tungsten silicon nitride (WSiN), and the second barrier pattern 640 may include titanium nitride (TiN).

According to a material of a substrate (base), a grain size of a material layer formed on the substrate may vary. As the grain size is decreased, the density of grain boundaries may be increased, and thus resistivity may be increased because the grain boundaries may interfere with movement of an electron.

For example, when a material layer formed of an oxide is used as the substrate, a grain size of a tungsten material layer formed on the substrate may be relatively large. On the other hand, when a material layer formed of a nitride is used as the substrate, a grain size of a tungsten material layer formed on the substrate may be relatively small. In this case, resistivity of the tungsten material layer formed on the nitride material layer may be greater than that of the tungsten material layer formed on the oxide material layer.

According to an embodiment of the present disclosure, the first conductive layer 650N and 650M formed in the NEAR region and the MIDDLE region may be formed using the first and second barrier patterns 630 and 640 as the substrate, and the first conductive layer 650F formed in the FAR region may be formed using the interlayer insulating layer 610 as the substrate. In this case, resistivity of each of the first conductive layer 650N and 650M formed in the NEAR region and the MIDDLE region may be greater than resistivity of the first conductive layer 650F formed in the FAR region.

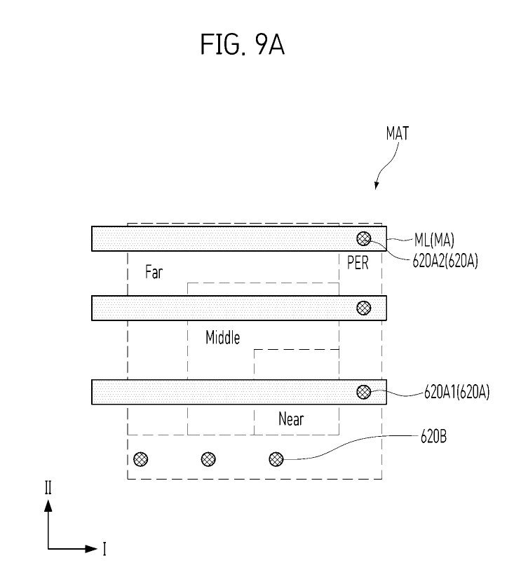

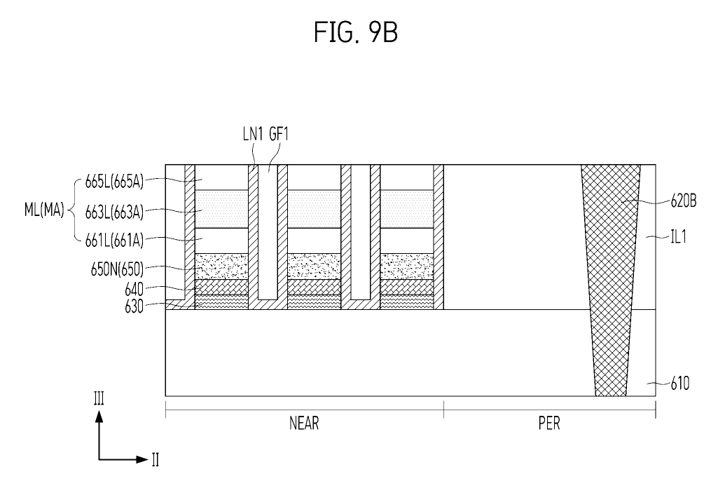

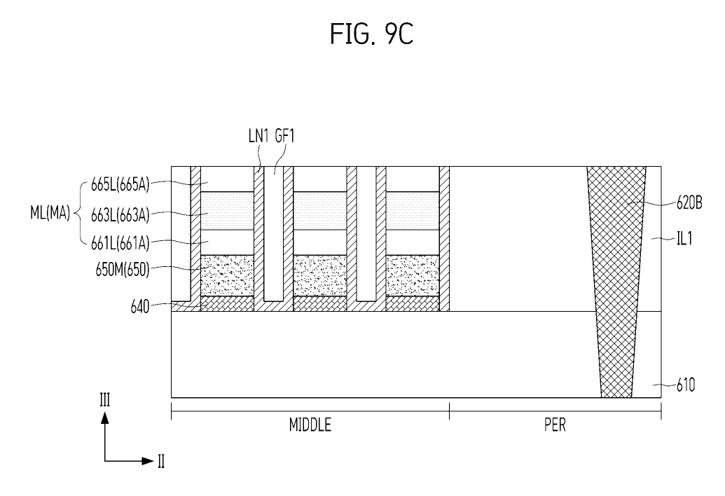

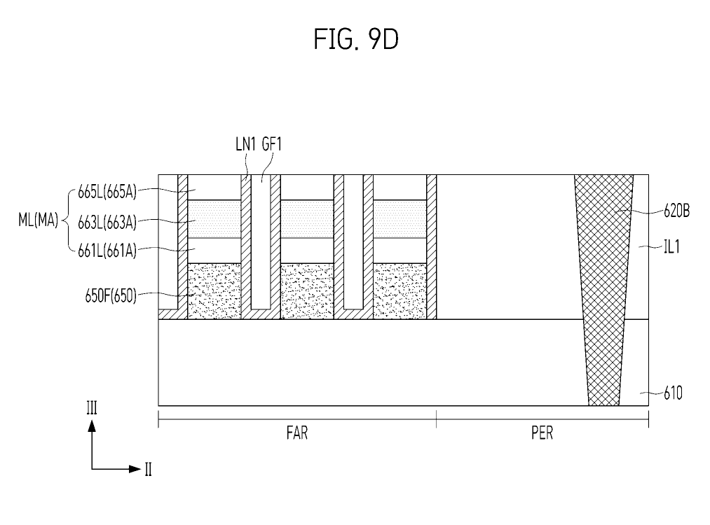

Referring to FIGS. 9A to 9D, first memory lines ML may be formed on the first conductive layer 650. First, the memory layer MA including a lower electrode layer 661A, a variable resistance layer 663A, and an upper electrode layer 665A may be formed on the first conductive layer 650. Subsequently, memory lines ML extending in a first direction I may be formed by etching the memory layer MA. Here, each of the memory lines ML may include a lower electrode line 661L, a variable resistance line 663L, and an upper electrode line 665L.

Subsequently, first conductive lines may be formed by etching the first conductive layer 650. Here, the first conductive lines may extend in the same direction as the memory lines ML. For example, the first conductive lines may extend in the first direction I. Here, the first conductive lines may be electrically connected to the first contact plugs 620A, respectively. The first conductive lines may be used as a word line or a bit line as row lines.

Subsequently, first liner patterns LN1 and first gap fill patterns GF1 may be formed on the memory lines ML and the first conductive lines. First, a first liner layer may be formed along a profile of the memory lines ML and the first conductive lines. Subsequently, a first gap fill layer may be formed on the first liner layer to fill a region between the memory lines ML. Subsequently, the first gap fill layer and the first liner layer may be planarized so that the memory lines ML are exposed. In this process, the first gap fill layer may be separated into the first gap fill patterns GF1, and the first liner layer may be separated into the first liner patterns LN1. Here, the first liner patterns LN1 may include an insulating material such as a nitride, and the first gap fill patterns GF1 may include an insulating material such as an oxide.

Subsequently, the memory lines ML formed in the peripheral circuit region PER may be etched and removed. For example, the memory lines ML may be etched and removed so that the interlayer insulating layer 610 is exposed. Subsequently, a first gap insulating layer IL1 may be formed at a position where the memory lines ML are etched and removed. Here, the first gap insulating layer IL1 may include an insulating material such as an oxide.

Subsequently, third contact plugs 620B may be formed in the peripheral circuit region PER. Third contact plugs 620B extending through the first gap insulating layer IL1 and the interlayer insulating layer 610 may be formed. The third contact plugs 620B may include a conductive material such as tungsten.

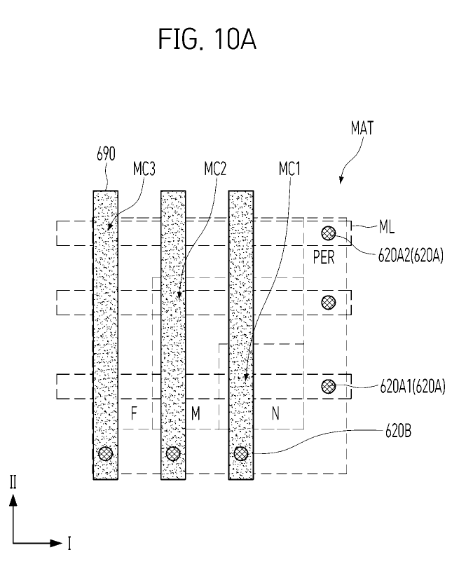

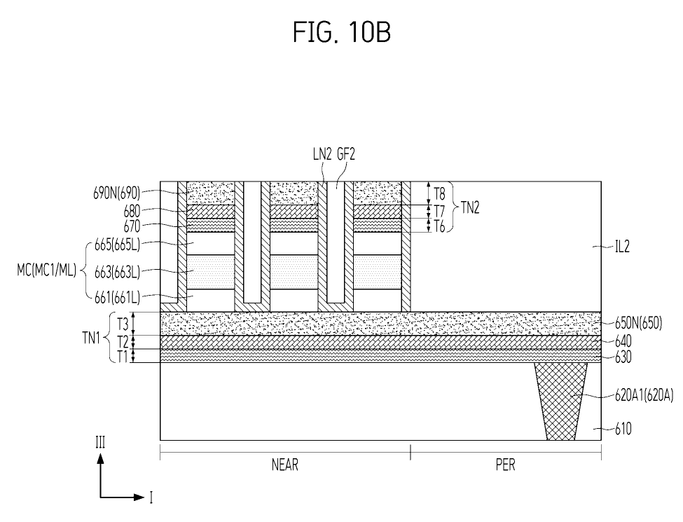

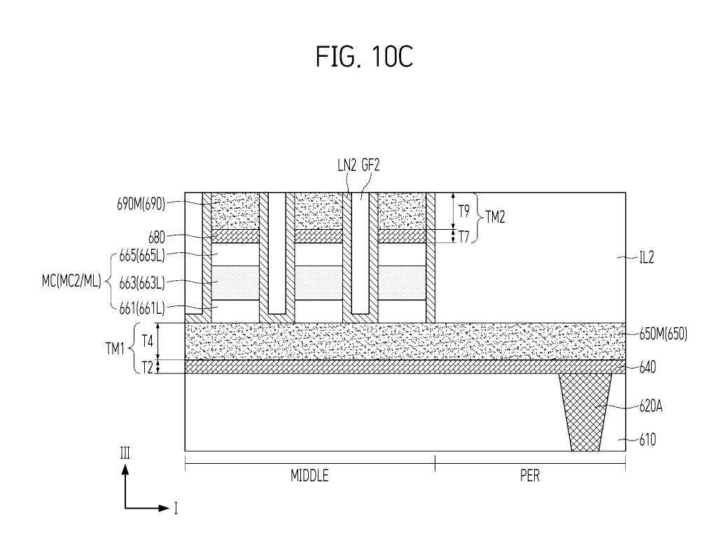

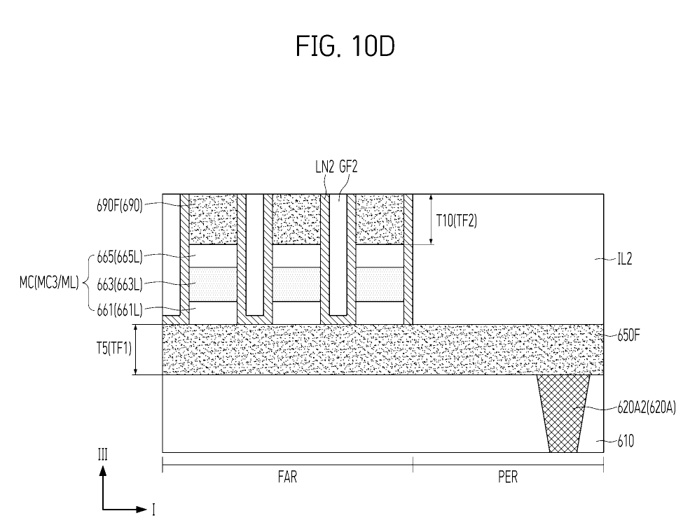

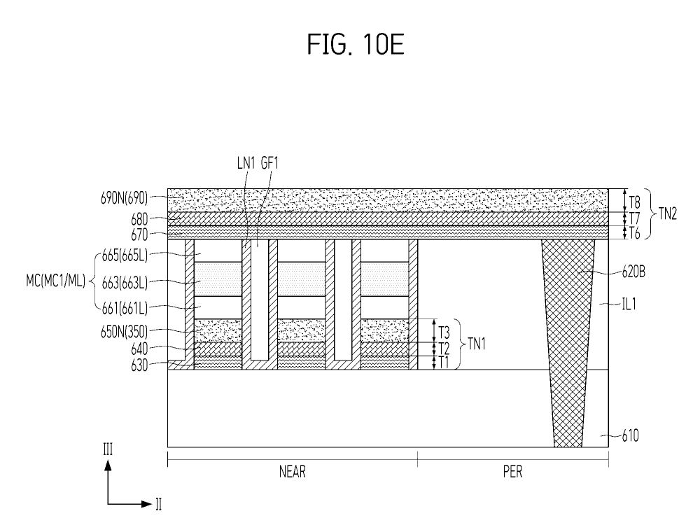

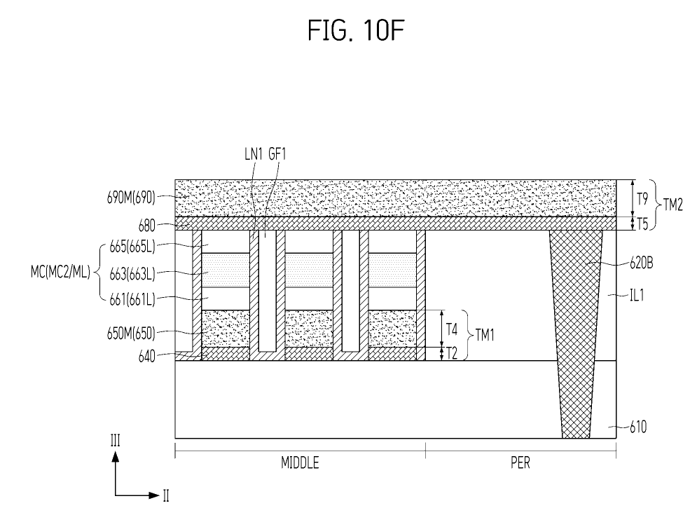

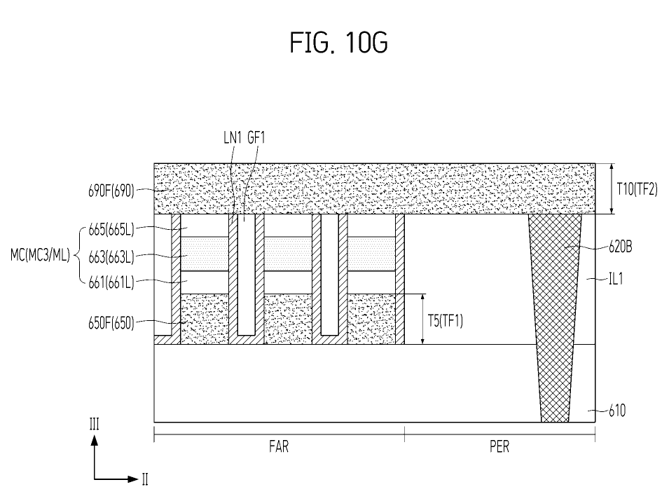

Referring to FIGS. 10A to 10G, fourth barrier patterns 670 may be formed on the memory lines ML. For example, the fourth barrier pattern 670 extending onto the third contact plug 620B on the memory lines ML of the NEAR region may be formed. The fourth barrier patterns 670 may include at least one of tungsten silicon nitride (WSiN) or titanium nitride (TiN).

Subsequently, fifth barrier patterns 680 may be formed on the fourth barrier patterns 670. In addition, the fifth barrier patterns 680 may be formed on the memory lines ML. For example, the fifth barrier pattern 680 extending onto the third contact plug 620B on the memory lines ML of the MIDDLE region may be formed. The fifth barrier patterns 680 may include at least one of tungsten silicon nitride (WSiN) or titanium nitride (TiN).

Subsequently, second conductive lines 690 may be formed on the first conductive lines. First, a second conductive layer may be formed on the fifth barrier patterns 680, the memory lines ML, and the third contact plugs 620B. In a process of forming the second conductive layer, because a step may occur between the NEAR region, the MIDDLE region, and the FAR region, the second conductive layer may be planarized to remove the step between the regions. For example, the second conductive layer may be planarized so that a sum TN2 of a thickness T6 of the fourth barrier pattern 670 of the NEAR region, a thickness T7 of the fifth barrier pattern 680, and a thickness T8 of the second conductive layer, a sum TM2 of the thickness T7 of the fifth barrier pattern 680 of the MIDDLE region and a thickness T9 of the second conductive layer, and a thickness T10(TF2) of the second conductive layer of the FAR region are substantially equal.

Subsequently, second conductive lines 690 extending in a second direction II crossing the first direction I may be formed by etching the second conductive layer. Here, the second conductive lines 690 may be electrically connected to the third contact plugs 620B, respectively. The second conductive lines 690 may be used as a bit line or a word line as column lines. A grain size of each of the second conductive lines 690N and 690M of the NEAR region and the MIDDLE region may be smaller than a grain size of the second conductive line 690F of the FAR region. The second conductive lines 690 may include a conductive material such as tungsten.

Subsequently, memory cells MC may be formed by etching the memory lines ML. Here, each of the memory cells MC may include a lower electrode pattern 661, a variable resistance pattern 663, and an upper electrode pattern 665. Here, the memory cell MC positioned in the NEAR region may be a first memory cell MC1, the memory cell MC positioned in the MIDDLE region may be a second memory cell MC2, and the memory cell MC formed in the FAR region may be a third memory cell MC3.

Subsequently, second liner patterns LN2 and second gap fill patterns GF2 may be formed on the memory cells MC and the second conductive lines 690. The second liner patterns LN2 and the second gap fill patterns GF2 may be formed similarly to a method of forming the first liner patterns LN1 and the first gap fill patterns GF1. The second liner patterns LN2 may include an insulating material such as a nitride, and the second gap fill patterns GF2 may include an insulating material such as an oxide.

Subsequently, the memory cells MC formed in the peripheral circuit region PER may be etched and removed. For example, the memory cells MC may be etched and removed so that the first conductive line 650 is exposed. Subsequently, a second gap insulating layer IL2 may be formed at a position where the memory cells MC are etched and removed. Here, the second gap insulating layer IL2 may include an insulating material such as an oxide.

The memory cells MC may be arranged in the first direction I and the second direction II. The memory cells MC may be positioned between the first conductive lines 650 and the second conductive lines 690, respectively. The memory cells MC may include the first memory cell MC1 in a first current path through the NEAR region, the second memory cell MC2 in a second current path through the MIDDLE region, and the third memory cell MC3 in a third current path through the FAR region.

The first current path including the first memory cell MC1 may have a first resistance. For example, the first current path from the first contact plug 620A1 to the third contact plug 620B includes the first barrier pattern 630, the second barrier pattern 640, the first conductive line 650N, the first memory cell MC1, and the second conductive line 690N. Here, the first current path may further include a path from the first memory cell MC1 to the second conductive line 690N through the third barrier pattern 670 and the fourth barrier pattern 680. Here, the first current path may have the first resistance.

The second current path including the second memory cell MC2 may have a second resistance. For example, the second current path from the first contact plug 620A to the third contact plug 620B includes the second barrier pattern 640, the first conductive line 650M, the second memory cell MC2, and the second conductive line 690M. Here, the second current path may further include a path from the second memory cell MC2 to the second conductive line 690M through the fourth barrier pattern 680. Here, the second current path may have the second resistance.

The third current path including the third memory cell MC3 may have a third resistance. For example, the third current path from the second contact plug 620A2 to the third contact plug 620B include the first conductive line 650F, the third memory cell MC3, and the second conductive line 690F.

Here, resistivity of each of the first, second, third, and fourth barrier patterns 630, 640, 670, and 680 may be greater than resistivity of each of the conductive lines 650 and 690. In addition, resistivity of each of the first and second conductive lines 650N, 650M, 690N, and 690M of the NEAR region and the MIDDLE region may be greater than resistivity of each of the first and second conductive lines 650F and 690F of the FAR region. In this case, the first resistance of the first current path, the second resistance of the second current path, and the third resistance of the third current path may be substantially equal. In other words, the first and second resistances each may be compensated substantially to be equal to the third resistance through a grain size of each of the first and second conductive lines 650N, 650M, 690N, and 690M as well as resistivity of each of the first, second, third, and fourth barrier patterns 630, 640, 670, and 680. Therefore, according to an embodiment of the present disclosure, an occurrence of overshooting in the first and second memory cells MC1 and MC2 may be substantially prevented, and a sensing margin may be secured by reducing a distribution difference of a threshold voltage between the first, second, and third memory cells MC1, MC2, and MC3.

For reference, although this drawing shows a case where the first and second barrier patterns 630 and 640 and the third and fourth barrier patterns 670 and 680 are formed in the NEAR region, embodiments of the present disclosure are not limited thereto. As an example, when the first and second barrier patterns 630 and 640 of the NEAR region are formed, the third and fourth barrier patterns 670 and 680 may not be formed. In other words, when resistances of the respective first, second, and third current paths become substantially equal through the first and second barrier patterns 630 and 640, the third and fourth barrier patterns 670 and 680 may be omitted. As another example, when the third and fourth barrier patterns 670 and 680 are formed, the first and second barrier patterns 630 and 640 may not be formed. Similarly, when the second barrier patterns 640 are formed, the fourth barrier patterns 680 of the MIDDLE region may be omitted, and vice versa.

According to the manufacturing method described above, at least one or more barrier patterns may be formed between the contact plug and the conductive line to compensate for the resistance of the current path including each of the memory cells of the NEAR region and the MIDDLE region, where the current path is relatively short.

In addition, a conductive line having a relatively small grain size may be formed, by using the barrier pattern as the substrate and forming the conductive line on the barrier pattern. Therefore, by making the total resistance of the current path to have a similar value regardless of a region and a current path, a sensing margin of the semiconductor device may be secured, and the memory cells may be substantially prevented from being damaged.

Although some embodiments of the present disclosure have been described with reference to the accompanying drawings, various embodiments of the present disclosure are not limited to the above-described embodiments. Various forms of substitution, modification, and change of the embodiments will be possible by those skilled in the art to which the present disclosure belongs, and these variations also belong to embodiments of the present disclosure.

What is claimed is:

1. A semiconductor device comprising:
a first row line;
a first column line positioned on the first row line;
a first memory cell positioned between the first row line and the first column line, a first current path including the first memory cell;
a third row line;
a third column line positioned on the third row line;
a third memory cell positioned between the third row line and the third column line, a third current path that includes the third memory cell being longer than the first current path;
first contact plugs including a first one and a third one, the first one and the third one of the first contact plugs electrically connected to the first row line and the third row line, respectively;
second contact plugs including a first one and a third one, the first one and the third one of the second contact plugs electrically connected to the first column line and the third column line, respectively;
a first barrier pattern positioned between the first one of the first contact plugs and the first row line; and
a second barrier pattern positioned between the first barrier pattern and the first row line.

2. The semiconductor device of claim 1, wherein the first current path from the first one of the first contact plugs to the first one of the second contact plugs includes the first barrier pattern, the second barrier pattern, the first row line, the first memory cell, and the first column line, and
wherein the third current path from the third one of the first contact plugs to the third one of the second contact plugs includes the third row line, the third memory cell, and the third column line.

3. The semiconductor device of claim 1, wherein the first current path has a first resistance, and
wherein the third current path has a third resistance substantially equal to the first resistance.

4. The semiconductor device of claim 1, wherein a sum of a thickness of the first barrier pattern, a thickness of the second barrier pattern, and a thickness of the first row line is substantially equal to a thickness of the third row line.

5. The semiconductor device of claim 1, wherein resistivity of each of the first barrier pattern and the second barrier pattern is greater than resistivity of each of the first row line and the third row line.

6. The semiconductor device of claim 5, wherein at least one of the first barrier pattern or the second barrier pattern includes tungsten silicon nitride or titanium nitride, and
wherein at least one of the first row line or the third row line includes tungsten.

7. The semiconductor device of claim 1, wherein the first barrier pattern and the second barrier pattern include different materials.

8. The semiconductor device of claim 7, wherein the first barrier pattern includes tungsten silicon nitride, and
wherein the second barrier pattern includes titanium nitride.

9. The semiconductor device of claim 1, wherein a grain size of the first row line is less than a grain size of the third row line.

10. The semiconductor device of claim 9, wherein resistivity of the first row line is greater than resistivity of the third row line.

11. The semiconductor device of claim 1, further comprising:
a third barrier pattern positioned between the first one of the second contact plugs and the first column line; and
a fourth barrier pattern positioned between the third barrier pattern and the first column line.

12. The semiconductor device of claim 1, wherein the first row line and the third row line are positioned on the first one and the third one of the first contact plugs, respectively, and
wherein the first column line and the third column line are positioned on the first one and the third one of the second contact plugs, respectively.

13. The semiconductor device of claim 1, further comprising:
a second row line, wherein the first contact plugs further include a second one electrically connected to the second row line;
a second column line positioned on the second row line, wherein the second contact plugs further include a second one electrically connected to the second column line;
a second memory cell positioned between the second row line and the second column line; and
a fifth barrier pattern positioned between the second one of the first contact plugs and the second row line.

14. The semiconductor device of claim 13, wherein the first current path from the first one of the first contact plugs to the first one of the second contact plugs includes the first barrier pattern, the second barrier pattern, the first row line, the first memory cell, and the first column line,
wherein the second current path from the second one of the first contact plugs to the second one of the second contact plugs includes the fifth barrier pattern, the second row line, the second memory cell, and the second column line, and
wherein the third current path from the third one of the first contact plugs to the third one of the second contact plugs includes the third row line, the third memory cell, and the third column line.

15. The semiconductor device of claim 14, wherein the second current path is longer than the first current path and shorter than the third current path.

16. The semiconductor device of claim 14, wherein the first current path has a first resistance,
wherein the second current path has a second resistance substantially equal to the first resistance, and
wherein the third current path has a third resistance substantially equal to the first resistance.

17. The semiconductor device of claim 13, wherein a sum of a thickness of the fifth barrier pattern and a thickness of the second row line is substantially equal to a sum of a thickness of the first barrier pattern, a thickness of the second barrier pattern, and a thickness of the first row line, and the sum of the thickness of the fifth barrier pattern and the thickness of the second row line is substantially equal to a thickness of the third row line.

18. The semiconductor device of claim 13, wherein resistivity of the fifth barrier pattern is greater than resistivity of each of the first row line, the second row line, and the third row line.

19. The semiconductor device of claim 18, wherein at least one of the first barrier pattern, the second barrier pattern, or the fifth barrier pattern includes tungsten silicon nitride or titanium nitride, and
wherein at least one of the first row line, the second row line, or the third row line includes tungsten.

20. The semiconductor device of claim 13, wherein the fifth barrier pattern includes a material different from a material of the first barrier pattern and includes a material substantially equal to the material of the second barrier pattern.

21. The semiconductor device of claim 20, wherein the first barrier pattern includes tungsten silicon nitride, and
wherein at least one of the second barrier pattern or the fifth barrier pattern includes titanium nitride.

22. The semiconductor device of claim 13, wherein a grain size of the second row line is greater than a grain size of the first row line and is less than a grain size of the third row line.

23. The semiconductor device of claim 13, wherein resistivity of the second row line is less than resistivity of the first row line and is greater than resistivity of the third row line.

24. The semiconductor device of claim 13, further comprising:
a third barrier pattern positioned between the first one of the second contact plugs and the first column line;
a fourth barrier pattern positioned between the third barrier pattern and the first column line; and
a sixth barrier pattern positioned between the second one of the second contact plugs and the second column line.

25. The semiconductor device of claim 13, wherein the first row line, the second row line, and the third row line are positioned on the first one, the second one, and the third one the first contact plugs, respectively, and
wherein the first column line, the second column line, and the third column line are positioned on the first one, the second one, and the third one of the second contact plugs, respectively.

26. A semiconductor device comprising:
a first row line having a first grain size;
a first column line positioned on the first row line;
a first memory cell positioned between the first row line and the first column line, a first current path including the first memory cell;
a second row line having a second grain size greater than the first grain size;
a second column line positioned on the second row line;
a second memory cell positioned between the second row line and the second column line, a second current path that includes the second memory cell being longer than the first current path;
first contact plugs including a first one and a second one, the first one and the second one of the first contact plugs electrically connected to the first row line and the second row line, respectively; and
second contact plugs including a first one and a second one, the first one and the second one of the second contact plugs electrically connected to the first column line and the second column line, respectively.

27. The semiconductor device of claim 26, further comprising:
a third row line having a third grain size greater than the second grain size;
a third column line positioned on the third row line; and
a third memory cell positioned between the third row line and the third column line, a third current path that includes the third memory cell being longer than the second current path.

28. The semiconductor device of claim 27, further comprising:
a first barrier pattern positioned between the first one of the first contact plugs and the first row line;
a second barrier pattern positioned between the first barrier pattern and the first row line; and
a fifth barrier pattern positioned between the second one of the first contact plugs and the second row line.

29. The semiconductor device of claim 28, wherein the first current path from the first one of the first contact plugs to the first one of the second contact plugs includes the first barrier pattern, the second barrier pattern, the first row line, the first memory cell, and the first column line,
wherein the second current path from the second one of the first contact plugs to the second one of the second contact plugs includes the fifth barrier pattern, the second row line, the second memory cell, and the second column line, and
wherein the third current path from the third one of the first contact plugs to the third one of the second contact plugs includes the third row line, the third memory cell, and the third column line.

30. The semiconductor device of claim 29, wherein the first current path has a first resistance,
wherein the second current path has a second resistance substantially equal to the first resistance, and
wherein the third current path has a third resistance substantially equal to the first resistance.

31. The semiconductor device of claim 28, wherein a sum of a thickness of the first barrier pattern, a thickness of the second barrier pattern, and a thickness of the first row line is substantially equal to a sum of a thickness of the fifth barrier pattern and a thickness of the second row line, and the sum of the thickness of the first barrier pattern, the thickness of the second barrier pattern, and the thickness of the first row line is substantially equal to a thickness of the third row line.

32. The semiconductor device of claim 28, wherein resistivity of each of the first barrier pattern, the second barrier pattern, and the fifth barrier pattern is greater than resistivity of each of the first row line, the second row line, and the third row line.

33. The semiconductor device of claim 32, wherein at least one of the first barrier pattern, the second barrier pattern, or the fifth barrier pattern includes tungsten silicon nitride or titanium nitride, and
wherein at least one of the first row line, the second row line, or the third row line includes tungsten.

34. The semiconductor device of claim 28, wherein the first barrier pattern includes a material different from a material of at least one of the second barrier pattern or the fifth barrier pattern, and
wherein the second barrier pattern and the fifth barrier pattern include a substantially equal material.

35. The semiconductor device of claim 34, wherein the first barrier pattern includes tungsten silicon nitride, and
wherein at least one of the second barrier pattern or the fifth barrier pattern includes titanium nitride.

36. The semiconductor device of claim 28, further comprising:
a third barrier pattern positioned between the first one of the second contact plugs and the first column line;
a fourth barrier pattern positioned between the third barrier pattern and the first column line; and
a sixth barrier pattern positioned between the second one of the second contact plugs and the second column line.

37. The semiconductor device of claim 27, wherein resistivity of the first row line is greater than resistivity of the second row line, and
wherein the resistivity of the second row line is greater than resistivity of the third row line.

38. The semiconductor device of claim 27, wherein the first row line, the second row line, and the third row line are positioned on the first one, the second one, and the third one of the first contact plugs, respectively, and
wherein the first column line, the second column line, and the third column line are positioned on the first one, the second one, and the third one of the second contact plugs, respectively.
